(19) United States
(12) Patent Application Publication
(10) Pub. No.: US 2016/0055912 A1
(43) Pub. Date: Feb. 25, 2016

(54) FLASH MEMORY DEVICE

(71) Applicant: SK hynix Inc., Icheon (KR)

(72) Inventors: Go Hyun LEE, Yongin (KR); Jin Ho KIM, Icheon (KR); Chang Man SON, Namyangju (KR); Sung Lae OH, Cheongju (KR)

(21) Appl. No.: 14/597,147

(22) Filed: Jan. 14, 2015

(30) Foreign Application Priority Data
Aug. 21, 2014 (KR) 10-2014-0109101

(51) Int. Cl. G11C 16/08

(52) U.S. Cl. CPC G11C 16/08

(57) ABSTRACT

A flash memory device is configured to reduce loading of a word line without increasing the size of a region. The flash memory device includes a cell array region including a word line structure; an X-decoder region disposed at one side of the cell array region, and including a pass transistor composed of a gate electrode, a source region, and a drain region; and a metal line coupled not only to the drain region of the pass transistor, but also to one side and the other side of the word line structure.

### CROSS-REFERENCE TO RELATED APPLICATION

The priority of Korean patent application No. 10-2014-0109101 filed on 21 Aug. 2014, the disclosure of which is hereby incorporated in its entirety by reference, is claimed.

### BACKGROUND OF THE INVENTION

Embodiments of the present invention relate to a flash memory device, and more particularly to a technology for reducing loading of a word line without increasing the size of an associated region.

A NAND flash memory acting as a non-volatile semiconductor memory device has a degree of integration and memory capacity that meet the requirements of DRAMs, so that the usage and availability of the NAND flash memory are rapidly increasing. The NAND flash memory is basically configured to have a specific structure in which a memory string connected in series to a plurality of memory cells is coupled in series between a bit line and a source line, and a plurality of memory strings are arranged in the NAND flash memory, resulting in a memory cell array.

Memory cells coupled to one word line across the memory string may form a page unit or a byte unit. In order to perform a read or write operation through selection of a predetermined cell of the flash memory, the corresponding cell is selected by word-line and bit-line selection signals. A decoder for selecting the word line will hereinafter be referred to as an X-decoder.

The X-decoder region is arranged adjacent to a cell array region. In the case of a memory cell located far from the X-decoder region, resistance-capacitance (RC) loading increases, so that it becomes difficult to perform programming of the memory cell and the programming speed of the memory cell is reduced.

In order to address this issue, there has recently been proposed an improved structure including two X-decoders configured to transmit a common word-line selection signal to one cell array region.

FIGS. 1A and 1B illustrate a conventional flash memory device. Referring to FIGS. 1A and 1B, the conventional flash memory device includes a cell array region and two X-decoder regions located at both sides of the cell array region. FIG. 1B is cross-sectional view illustrating the semiconductor device taken along the line A-A′ FIG. 1A.

The X-decoder region is arranged at left and right sides of the cell array region, and includes a block switch and a pass transistor. The block switch includes a block word line (BLKWL), and the block word line (BLKWL) is coupled to pass transistors composed of high-voltage transistors.

A source region of the pass transistor is coupled to a ground drain selection line (GDSL) and a ground source selection line (GSSL). A drain region of the pass transistor is coupled to one side of the word-line structure of the cell array region through a contact. That is, the pass transistors of the X-decoder regions arranged at both sides of the cell region array are respectively coupled to one side and the opposing side of the word line.

In the above-mentioned conventional flash memory device, each respective X-decoder regions is configured to control only one half of the cell array region, so that the flash memory device can address a problem in which the program speed is deteriorated by RC loading.

In recent times, as the degree of integration of memory devices increases, the number of word lines to be selected also increases, so that the size of the region occupied by a decoding circuit increases. In addition, memory cell regions are becoming more highly integrated, and the region occupied by a unit memory cell is reduced in size according to a design rule. However, the size of an X-decoder may become larger to accommodate the additional circuitry, which makes it more difficult to reduce chip size.

### BRIEF SUMMARY OF THE INVENTION

Various embodiments of the present disclosure are directed to providing a flash memory device that substantially obviates one or more problems due to limitations and disadvantages of the related art.

An embodiment relates to a flash memory device in which an X-decoder region is arranged only at one side of a cell array region, so that the region needed for arrangement of the conventional X-decoder region can be guaranteed and at the same time resistance-capacitance (RC) load of word lines can be reduced.

In accordance with an aspect of the embodiment, a flash memory device comprising: a cell array region including a word line structure extending in a first direction; an X-decoder region disposed at a first side of the cell array region, and including a pass transistor including a gate electrode, a source region, and a drain region; and a metal line coupled to the drain region of the pass transistor, and to both the first side and an opposing second side of the word line structure.

The metal line may include a drain selection line and a source selection line. The flash memory device may further include: a plurality of source lines and a bit line formed over the word line structure disposed at a same level of the flash memory device.

The bit line has a line shape extended along a second direction crossing the first direction.

The metal line is formed between two of the plurality of source lines at the same level. The metal line is formed at a higher level than the bit line.

The X-decoder region may further include a block switch transistor. The block switch transistor may be coupled to the pass transistor.

The word line structure includes an alternating stack of word-line conductive layers and insulation layers. The flash memory device may further include: a step-shaped contact region disposed at the first and second sides of the word line structure.

The flash memory device may further include a contact plug formed over the contact region. The word line structure may be coupled to the metal line through the contact plug.

The source region of the pass transistor may be coupled to a ground drain selection line (GDSL) and a ground source selection line (GSSL).

In accordance with an aspect of the embodiment a memory device comprising: a plurality of cells disposed in a cell array region; a word line structure extending from a first side of the cell array region to a second side of the cell array region; an X-decoder disposed only on the first side of the cell array region; a source line extending in parallel to the word line structure; and a metal line coupled to opposing sides of the word line structure through opposing contact plugs.

The metal line is coupled to a drain region of a pass transistor through a first contact plug extending between the drain region and a portion of the metal line disposed on the first side of the cell array region.

The word line structure is disposed on a first level, the source line is disposed on a second level above the first level, a plurality of bit lines are disposed on a third level above the second level, and the metal line is disposed on a fourth level above the third level.

The metal line is disposed on a same level as the source line.

It is to be understood that both the foregoing general description and the following detailed description are exemplary and explanatory and are intended to provide further explanation of the claims.

### BRIEF DESCRIPTION OF THE DRAWINGS

FIGS. 1A and 1B are a plan view and a cross-sectional view illustrating a conventional flash memory device.

FIGS. 2A and 2B are a plan view and a cross-sectional view illustrating a flash memory device according to an embodiment of the present disclosure.

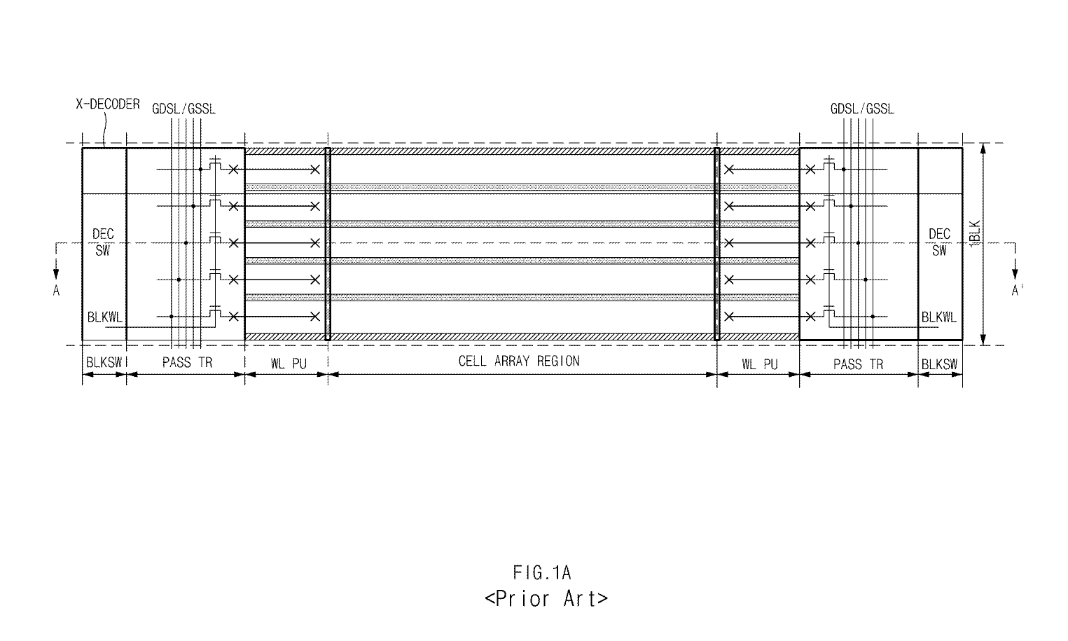

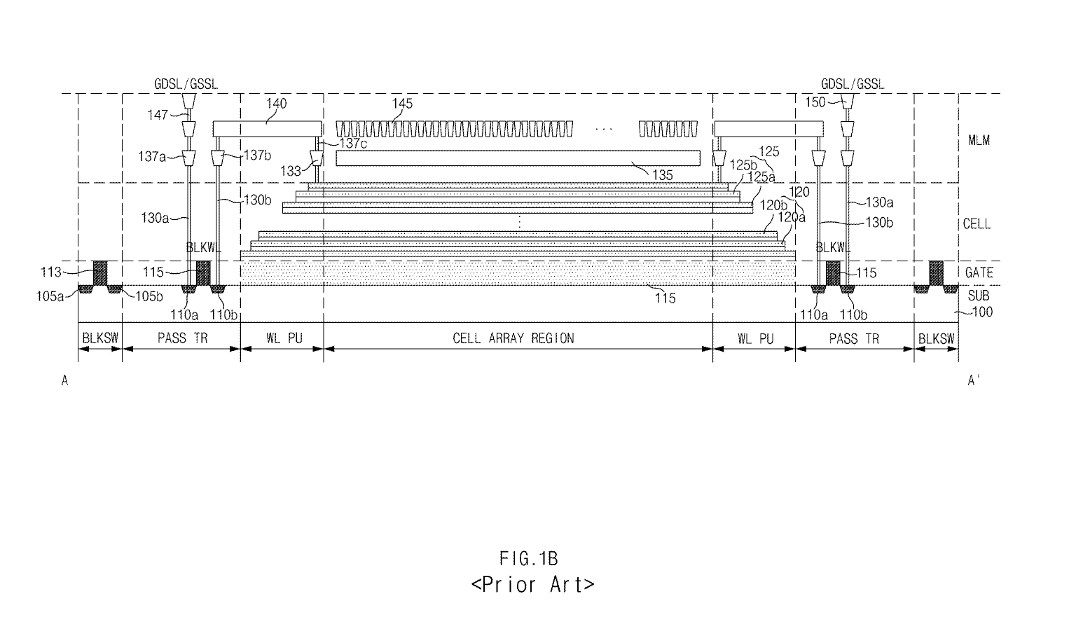

### DESCRIPTION OF EMBODIMENTS

Reference will now be made in detail to certain embodiments, examples of which are illustrated in the accompanying drawings. Wherever possible, the same reference numbers will be used throughout the drawings to refer to the same or like parts. In the following description, a detailed description of related known configurations or functions incorporated herein will be omitted when it may make the subject matter less clear.

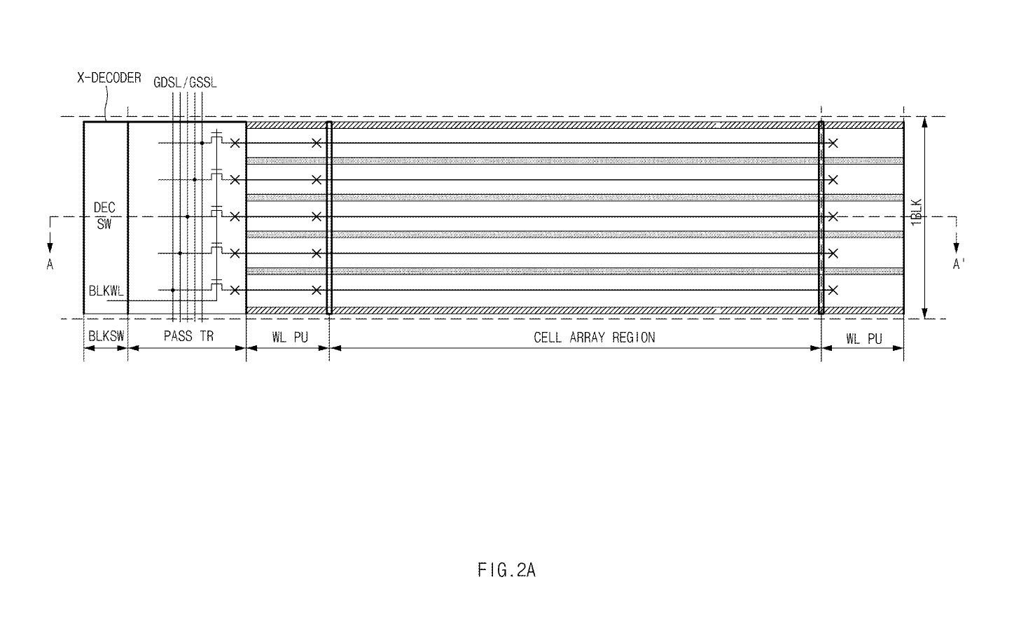

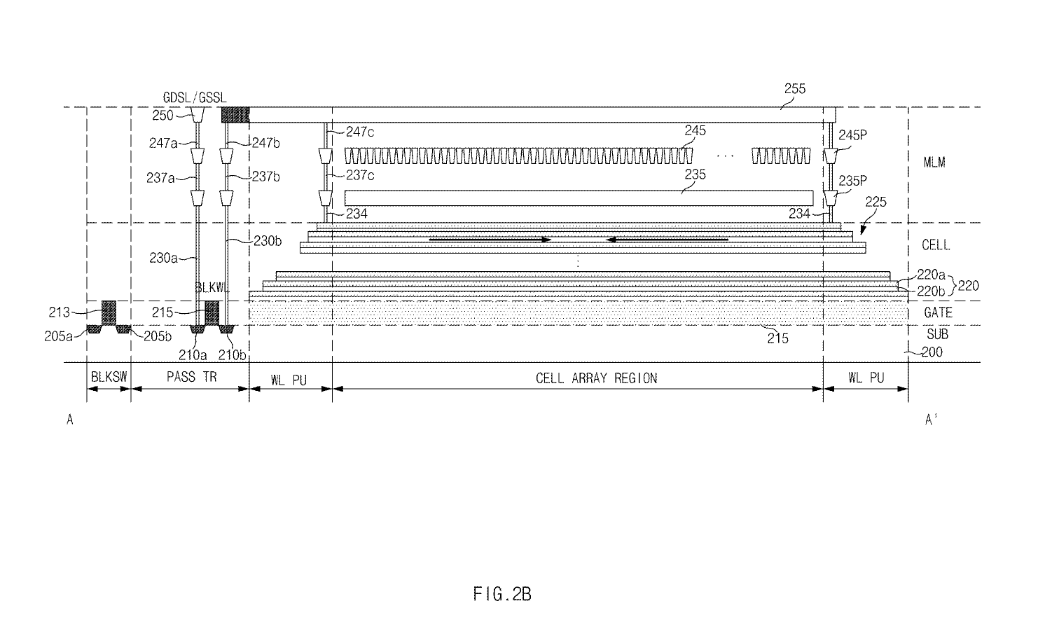

FIG. 2A is a plan view and a cross-sectional view illustrating a flash memory device according to an embodiment.

A cell array region is shown in FIG. 2A. The cell array region may include a plurality of memory blocks (BLK), and the memory blocks may include a plurality of word lines (WL), a plurality of bit lines (BL), and a plurality of memory cells, and may store data therein.

An X-decoder region is arranged at one side of the cell array region. Upon receiving a row address (RADD) from a control circuit, the X-decoder region may apply the operation voltage to a plurality of word lines (WL) and the drain and source selection lines (DSL, SSL) of the cell array region. The X-decoder region may include a block switch (BLKSW) and a pass transistor (PASS TR).

The block switch (BLKSW) may include a block word line (BLKWL), and the block word line may be coupled to gate electrodes of the pass transistor (PASS TR) which includes of a plurality of high-voltage transistors.

The pass transistor (PASS TR) performs switching for applying a predetermined voltage to the word line (WL) of the cell array region, and the pass transistors (PASS TR) are turned on when the block word line (BKWL) is precharged with an operation voltage (VPP) level. The source region of the pass transistor (PASS TR) is coupled to a ground drain selection line (GDSL) and a ground source selection line (GSSL), and the drain region is coupled to a metal line 255. In various embodiments, the metal line 255 may be a source selection line (SSL) and/or a drain selection line (DSL).

The metal line 255 coupled to the drain region of the pass transistor (PASS TR) may be coupled to opposing sides of the word line of the cell array region through contact plugs coupled to the word line structure. A bias voltage may be applied to a word line located opposite to the X-decoder region through the metal line 255 coupled to the X-decoder region. A metal line 255 may be a drain selection line or a source selection line (SSL, DSL). Therefore, the X-decoder region may be arranged only at one side of the cell array region, so that the region occupied by the X-decoder is smaller than a conventional X-decoder region of the related art, and a metal line having a low RC load is coupled to the word line, reducing the number of RC loading times.

FIG. 2B illustrates a flash memory device according to an embodiment of the present disclosure. FIG. 2B is cross-sectional view illustrating the semiconductor device taken along the line A-A′ FIG. 2A.

Referring to FIG. 2B, a word line structure 220 and a step-shaped connection portion (WL PU) acting as a contact region 225 are formed over a semiconductor substrate 200 of the cell array region. The word line structure 220 includes a multi-layered word line conductive layer 220a and an insulation layer 220b that are alternately stacked. The contact region 225 is coupled to the word line structure 220, and is patterned in the form of a plurality of steps. For example, a lower word-line conductive layer 220a protrudes horizontally from an upper word-line conductive layer 220a, so that the top surface of the lower word-line conductive layer 220a is exposed.

A source line SL 235 and a source line pad 235P are formed over the word line structure 220, and a bit line 245 and a bit line pad 245P are then formed over the source line SL 235 and the source line pad 235P. Generally, the source line SL 235 may be formed as a metal line M0, and the bit line may be formed as a metal line M1. Here, metal line designations Mn, where n is an integer, refer to different types of metal lines in a semiconductor device. More specifically, the Mn designations refer to a level on which a metal line is located, where higher integer values for n indicate higher levels on the semiconductor device. In an embodiment, the source line 235 may have a line shape extended along a first direction which is a long-axis direction of the word line structure 220. In addition, the bit line 245 may have a line shape extending along a second direction crossing the first direction of the word line structure 220.

An X-decoder region may be formed at a first side of the cell array region. Conventionally, the X-decoder region may be disposed at two opposing sides of the cell array region. However, in an embodiment of the present disclosure, an X-decoder region is disposed only at one side of the cell array region. Therefore, the region occupied by the X-decoder region can be reduced in size relative to a conventional device.

The X-decoder region may include a block switch transistor BLKSW and a pass transistor (PASS TR).

The block switch (BLKSW) and the pass transistor (PASS TR) may be composed of gate electrodes (213, 215), source regions (205a, 210a), and drain regions (205b, 210b).

The block switch (BLKSW) transistor may include a block word-line (BLKWL), and the block word-line (BLKWL) may be coupled to gate electrodes 215 of the pass transistor (PASS TR) as shown in FIG. 2A. The source region 210a of the pass transistor (PASS TR) may be coupled to a source line pad 235P through a first contact plug 230a, and may be coupled to the bit line pad 245P through a second contact plug 237a formed over the source line pad 235P. The source region 210a may be coupled to the ground drain selection line (GDSL) and the ground source selection line (GSSL) through a third contact plug 247a formed over the bit line pad 245P. That is, the source region 210a of the pass transistor (PASS TR) may be electrically coupled to the ground selection lines (GDSL/GSSL).

In addition, the drain region 210b of the pass transistor (PASS TR) may be coupled to the source line pad 235P through a first contact plug 230b, and may be coupled to the bit line pad 245P through a second contact plug 237b formed over the source line pad 235P. The drain region 210b may be coupled to metal line 255 through a third contact plug 247b formed over the bit line pad 245P. The metal line 255 may include a source selection line (SSL) and a drain selection line (DSL). A layer including the metal line 255 is not limited only to a layer formed over the bit line as shown in FIG. 2B. In other embodiments, various modifications may be applied to the layer.

For example, the metal line 255 may be a metal line M0 disposed at the same level as the source line 235 in FIG. 2B. In other words, in an embodiment, the metal line 255 may be disposed between the source lines 235 at metal line level M0.

In some embodiments, if the metal line M0, the metal line M1, and the metal line M2 are respectively used as a source line, a bit line, and a mesh-shaped source line, a metal line M3 formed over the above lines may be used as the metal line 255. Thus, while FIG. 2B shows metal line 255 being disposed above bit line 245, source line 235 and word lines 220, in other embodiments, metal line 255 may be disposed at a level of one of the underlying structures.

The drain region 210b of the pass transistor (PASS TR) may be electrically coupled to the metal line 255 through one or more contact plug.

A fourth contact plug 234 may be formed over both sides of the uppermost word line conductive layer 220a of the word line structure 220 of the cell array region, and the fourth contact plug 235 may be coupled to the source line pad 235P. A fifth contact plug 237c may be formed over the source line pad 235P, and may be coupled to the bit line pad 245P through the fifth contact plug 237c. A sixth contact plug 247c may be formed over the bit line pad 245c, and may be coupled to the metal line 255 through the sixth contact plug 247c.

As described above, the metal line 255 coupled to the drain region of the pass transistor (PASS TR) may be coupled to both sides of the word line 220 of the cell array region through one or more contact plug. A bias voltage may also be applied to a portion of the word line 220 located opposite to the X-decoder region through the metal line 255 connected to the X-decoder region, for example, through the drain selection line/source selection line (DSL/SSL).

As a result, the X-decoder region can be disposed only at one side of the cell array region, so that the region occupied by the X-decoder is reduced in size relative to a conventional device. Moreover, the metal line having low RC loading is coupled to the word line, resulting in reduction of the number of RC loading times.

As is apparent from the above description, a flash memory device according to an embodiment may provide one or more of the following effects.

An X-decoder region is arranged only at one side of a cell array region, so that the region that has been occupied by the X-decoder region is reduced in size.

A metal line having lower RC load than a word line is connected to two opposing sides of the word line, so that the number of loading times of a word line can be reduced.

Those skilled in the art will appreciate that embodiments of the present disclosure may be carried out in other ways than those set forth herein without departing from the scope and characteristics of these embodiments. The above embodiments are therefore to be construed in all aspects as illustrative and not restrictive.

The above embodiments of the present disclosure are illustrative and not limitative. Various alternatives and equivalents are possible. The invention is not limited by the type of deposition, etching polishing, and patterning steps described herein. Nor are embodiments limited to any specific type of semiconductor devices. For example, embodiments may be implemented in a dynamic random access memory (DRAM) device or non volatile memory device. Other additions, subtractions, or modifications are obvious in view of the present disclosure and are intended to fall within the scope of the appended claims.

What is claimed is:

1. A flash memory device comprising:
a cell array region including a word line structure extending in a first direction;
an X-decoder region disposed at a first side of the cell array region, and including a pass transistor that includes a gate electrode, a source region, and a drain region; and
a metal line coupled to the drain region of the pass transistor, and to both the first side and an opposing second side of the word line structure.

2. The flash memory device according to claim 1, wherein the metal line includes a drain selection line and a source selection line.

3. The flash memory device according to claim 1, further comprising:
a plurality of source lines disposed at a same level of the flash memory device and a bit line formed over the word line structure.

4. The flash memory device according to claim 3, wherein the source line has a line shape that extends in the first direction.

5. The flash memory device according to claim 4, wherein the bit line has a line shape extended along a second direction crossing the first direction.

6. The flash memory device according to claim 3, wherein the metal line is formed between two of the plurality of source lines at the same level.

7. The flash memory device according to claim 3, wherein the metal line is formed at a higher level than the bit line.

8. The flash memory device according to claim 1, wherein the X-decoder region further includes a block switch transistor.

9. The flash memory device according to claim 1, wherein the block switch transistor is coupled to the pass transistor.

10. The flash memory device according to claim 1, wherein the word line structure includes an alternating stack of word-line conductive layers and insulation layers.

11. The flash memory device according to claim 1, further comprising:
a step-shaped contact region disposed at the first and second sides of the word line structure.

12. The flash memory device according to claim 1, further comprising:
a contact plug formed over the contact region.

13. The flash memory device according to claim 6, wherein the word line structure is coupled to the metal line through the contact plug.

14. The flash memory device according to claim 1, wherein the source region of the pass transistor is coupled to a ground drain selection line (GDSL) and a ground source selection line (GSSL).

15. A memory device comprising:
a plurality of cells disposed in a cell array region;
a word line structure extending from a first side of the cell array region to a second side of the cell array region;
an X-decoder disposed only on the first side of the cell array region;
a source line extending in parallel to the word line structure; and
a metal line coupled to opposing sides of the word line structure through opposing contact plugs.

16. The memory device of claim 15, wherein the metal line is coupled to a drain region of a pass transistor through a first contact plug extending between the drain region and a portion of the metal line disposed on the first side of the cell array region.

17. The memory device of claim 16, wherein the word line structure is disposed on a first level, the source line is disposed on a second level above the first level, a plurality of bit lines are disposed on a third level above the second level, and the metal line is disposed on a fourth level above the third level.

18. The memory device of claim 16, wherein the metal line is disposed on a same level as the source line.
